(19) United States
(12) Patent Application Publication
(10) Pub. No.: US 2010/0330738 A1
(43) Pub. Date: Dec. 30, 2010

(54) Oxide semiconductor target and manufacturing method of oxide semiconductor device by using the same

(75) Inventors: Hiroyuki Uchiyama, Musashimurayama (JP); Hironori Wakana, Tokorozawa (JP); Tetsufumi Kawamura, Kodaira (JP); Fumi Kurita, Shimamoto (JP); Hideko Fukushima, Yasugi (JP)

Correspondence Address: MILES & STOCKBRIDGE PC, 1751 PINNACLE DRIVE, SUITE 500, MCLEAN, VA, 22102-3833, US

(73) Assignee: HITACHI METALS, LTD.

(21) Appl. No.: 12/662,305

(22) Filed: Apr. 9, 2010

(30) Foreign Application Priority Data
Apr. 13, 2009 (JP) 2009-096937

(51) Int. Cl. H01L 21/36; C23C 14/35; C23C 14/34; H01L 21/365

(52) U.S. Cl. 438/104; 204/298.13; 204/192.25; 257/E21.461; 257/E21.463

(57) ABSTRACT

An oxide semiconductor target of a ZTO (zinc tin complex oxide) type oxide semiconductor material of an appropriate (Zn/(Zn+Sn)) composition having high mobility and threshold potential stability and with less restriction in view of the cost and the resource and with less restriction in view of the process, and an oxide semiconductor device using the same, in which a sintered Zn tin complex oxide with a (Zn/(Zn+Sn)) composition of 0.6 to 0.8 is used as a target, the resistivity of the target itself is at a high resistance of 1 Ωcm or higher and, further, the total concentration of impurities is controlled to 100 ppm or less.

### CLAIM OF PRIORITY

The present application claims priority from Japanese patent application JP 2009-096937 filed on Apr. 13, 2009, the content of which is hereby incorporated by reference into this application.

### BACKGROUND OF THE INVENTION

1. Field of the Invention

The present invention concerns an oxide semiconductor target material for depositing an oxide semiconductor material and it particularly relates to a material technique of a sintered body target used for sputtering. Further, the invention also includes a technique relating to a method of manufacturing an oxide semiconductor thin film transistor manufactured by using the target material and utilized as a switching device for a liquid crystal display or an organic EL display.

2. Description of the Related Art

In recent years, display devices have been developed rapidly from display using a cathode ray tube to a planar type display device referred to as a flat panel display (FPD) such as a liquid crystal panel or a plasma display. In the liquid crystal panel, a-Si or polysilicon thin film transistors are utilized as a switching device as a device concerning pixel switching by liquid crystals. Recently, FPD using the organic EL has been expected with an aim of further increasing the area and providing flexibility.

However, since the organic EL device is a self light emitting device of obtaining direct emission by driving an organic semiconductor layer, a characteristic as a current driving device is required for the thin film transistor different from existent liquid crystal displays.

On the other hand, for future FPDs, provision of new functions such as further increase of the area and flexibility has also been demanded and it is required that they have high performance as an image display device, as well as can cope with a large area process and cope with a flexible substrate. With the background described above, application of an oxide semiconductor which is transparent and having a band gap as large as about 3 eV has been studied in recent years as a thin film transistor for the display device and has also been expected for application to thin film memories, RFIDs, etc. in addition to the display device (refer, for example, to Japanese Patent Application Laid-Open Publication No. 2006-165532, columns [0009] to [0052], Japanese Patent Application Laid-Open Publication No. 2006-173580, columns [0009] to [0032], “High mobility transparent thin-film transistors with amorphous zinc tin oxide channel layer” by H. Q. Chiang and other three, APPLIED PHYSICS LETTERS, Vol. 86, 013503 (2005), “Combinatorial study of zinc tin oxide thin-film transistors” by M. G. McDowell and other two, APPLIED PHYSICS LETTERS. Vol. 92, 013502 (2008). The technique of using the oxide material to a transparent conductive film or a transparent electrode film is disclosed, for example, in Japanese Patent Application Laid-Open Publication No. 2006-196200, columns [0009] to [0032], Japanese Patent Application Laid-Open Publication No. 2006-194926, columns [0009] to [0030], Japanese Patent Application Laid-Open Publication No. 2007-277075, columns [0009] to [0058], and Japanese Patent Application Laid-Open Publication No. 2007-250369, columns [0005] to [0006].

### SUMMARY OF THE INVENTION

In recent years, since the function as a current driving device is demanded for the thin film transistor used for the organic EL display device expected as a self light-emitting and highly fine display, a high reliability is required in view of suppression for threshold potential shift and durability. However, in a-Si used mainly for the switching of existent liquid crystal displays, since the threshold potential shift greatly exceeds about 2V which is controlled easily by a compensation circuit, it is considered that this is difficult to be applied as the thin film transistor for the organic EL displays.

On the other hand, thin film transistors using, for example, IGZO (indium gallium zinc complex oxide) capable of suppressing the potential shift which is the defect of zinc oxide is described in Japanese Patent Application Laid-Open Publication No. 2006-165532, columns [0009] to [0052] and Japanese Patent Application Laid-Open Publication No. 2006-173580, columns [0009] to [0032], instead of transparent oxide transistors using zinc oxide and tin oxide which have been known long since, and the possibility of attaining a new semiconductor device by a thin film process can be expected. Particularly, for IGZO, those having better subthreshold swing than those of polysilicon have also been confirmed, and application use can be expected not only to the displays but also to devices requiring ultra-low voltage operation or ultra-low power consumption.

For example, a thin film transistor using an oxide semiconductor such as of IGZO to a channel layer has a sufficient characteristic with a mobility of about 1 to 50 cm²/Vs and an on-off ratio of 10⁶ or more as a switching/current driving device for a liquid crystal display or an organic EL display. In addition, since a process at room temperature such as sputtering is possible, it has a composite advantage such as easy provision of flexibility. That is, this shows that a high quality thin film transistor equivalent with polysilicon which requires high temperature treatment can be attained by room temperature process such as a sputtering method at a low cost.

However, oxide semiconductor materials such as IGZO, ITO, IZO, and IGO lack in versatility since they are rare metals and contain expensive indium.

In view of the above, oxide semiconductor materials which are advantageous in view of the resource or the cost are to be sought. While, zinc oxide as a first candidate is a material with no problem in view of the stable supply or the cost but zinc itself belongs to a material system inherently having high vapor pressure and involves a problem in view of the stability after deposition, etc. In the application field for the semiconductor film different from that for the present case, zinc oxide materials with addition of aluminum or gallium have been expected long since as a transparent conductive film or a transparent electrode instead of ITO (indium tin complex oxide), but zinc oxide type materials which are so favorable as completely substituting ITO have not yet been put to practical use. Particularly, there exists a significant problem that the resistivity suffers from a significant effect depending on the working circumstance such as moisture or oxygen.

In the application for semiconductors not requiring carriers, which is different from the transparent electrode, zinc oxide with no addition of impurities are used but, also in this case, it has been known that the potential shift or the mobility suffers from a circumstantial effect due to moisture or oxygen. Further, since zinc oxide is a micro crystal material in which hexagonal columnar grains tend to grow in the direction perpendicular to a substrate since it has a wurtzite-type crystal structure and it also involves a significant drawback of deterioration of the mobility and the threshold potential shift due to grain boundary scattering since it has a number of crystal grain boundaries in the direction parallel to the substrate.

Accordingly, it is necessary to provide a novel oxide semiconductor material which belongs to a material system with less restriction in view of the resource and capable of suppressing the threshold potential shift and attaining a high mobility. In recent years, as described, for example, by H. Q. Chiang, and other three in “High mobility transparent thin-film transistors with amorphous zinc tin oxide channel layer”, APPLIED PHYSICS LETTERS, Vol. 86, 013503 (2005), there is an example of a thin film transistor using an amorphous type ZTO (zinc tin complex oxide) with no grain boundaries which realizes a high mobility of 20 to 50 cm²/Vs. In the material system, the problem of the resource or cost and the semiconductor characteristic may be compatible.

However, in “High mobility transparent thin-film transistors with amorphous zinc tin oxide channel layer”, APPLIED PHYSICS LETTERS, Vol. 86, 013503 (2005) by H. Q. Chiang, and other three, since a film is deposited by a sputtering method using a sputtering target of a relatively tin-rich composition in which the zinc to tin composition is 1:1, this involves a problem that fabrication by wet etching used customarily is actually difficult.

On the other hand, there is also an example of studying composition of zinc and tin by using a combinatorial method (method of collectively preparing, matrices of different compositions in a great amount and evaluating and optimizing them as described, for example, by M. G. McDowell and other two, in “Combinatorial study of zinc tin oxide thin-film transistors”, APPLIED PHYSICS LETTERS, Vol. 92, 013502 (2008). While good mobility (about 10 cm²/Vs) is obtained only for the Zn/(Zn+Sn) composition of about 0.3 or about 0.7, there may be a high possibility that such a good characteristic is obtained simply at sample positions where the film density is good and Zn/(Zn+Sn) compositions corresponding thereto in relation with the configuration of apparatus and, accordingly, it cannot be said that physical analysis can really be attained.

Further, at the Zn/(Zn+Sn) composition of about 0.7, the threshold potential is extremely high as 15V or higher and this cannot be suitable at all to the practical use of low power consumption devices. While the threshold potential is about 8V at the composition of 0.3, fabrication is difficult in a region where the Sn composition is high in the same manner as the example described above. Then, ZTO material compositions suitable to practical use have now yet been found in the known examples described above.

The present invention intends to provide an appropriate Zn/(Zn+Sn) composition for a ZTO (zinc tin complex oxide) type oxide semiconductor material having high mobility and threshold potential stability and with less restriction in view of the cost and the resource and restriction in view of the process. Further, the invention intends to attain a target material therefor and provide a method of manufacturing a good oxide semiconductor device which is prosperous as a thin film transistor, etc. for switching and current driving of organic EL displays or liquid crystal displays in the next generation.

Among the inventions disclosed in the present application, the outline of typical inventions is to be briefly described as below.

The invention provides an oxide semiconductor target which is a sintered oxide with an aim of forming a thin film oxide semiconductor including zinc oxide and tin oxide (IV or VI) as main ingredients in which the Zn to tin composition (zinc/(zinc+tin)) is from 0.6 to 0.8 and the electric resistivity of the sintered product is 1 Ωcm or higher.

Further, the invention provides a method of manufacturing an oxide semiconductor device which includes using the oxide semiconductor target described above and depositing an oxide semiconductor film as a channel layer by a sputtering method using high frequency.

According to the method described above, it is possible to provide an appropriate Zn/(Zn+Sn) composition for a ZTO (zinc tin complex oxide) type oxide semiconductor material having high mobility and threshold potential stability, and with less restriction in view of the cost and the resource and less restriction in view of the process. Further, it is possible to attain a target material therefor and provide a method of manufacturing a good oxide semiconductor device which is prosperous as a thin film transistor or the like for switching or current driving organic EL displays or liquid crystal displays in the next generation.

### BRIEF DESCRIPTION OF THE DRAWINGS

FIG. 1 is a graph showing a relation between a Zn/(Zn+Sn) composition in a zinc tin complex oxide target according to a preferred embodiment and characteristics of a thin film transistor (mobility, threshold potential shift (ΔVth));

FIG. 2 is a graph showing a relation between the Zn/(Zn+Sn) composition in the zinc tin complex oxide target according to the preferred embodiment and an etching rate by an oxalic acid type etching solution;

FIG. 3 is a schematic cross sectional view of a thin film transistor used for the evaluation of semiconductor characteristics of a zinc tin complex oxide target according to the preferred embodiment;

FIG. 4 is a graph showing typical semiconductor characteristics of a thin film transistor formed by RF sputtering by utilizing the zinc tin complex oxide target according to the preferred embodiment;

FIG. 5 is a photograph showing a difference in the appearance between a high resistance target used for semiconductor application (white) and a conductive target used for transparent electrode application (black) of zinc tin complex oxide target;

FIG. 6 is a schematic view of a sputtering apparatus using a zinc tin complex oxide target according to a first embodiment;

FIG. 7 is a cross sectional view of a bottom gate top contact type thin film transistor according to the first embodiment (the upper portion shows a fragmentary cross sectional view);

FIG. 8A to FIG. 8E are flow charts for explaining a method of manufacturing a bottom gate top contact type thin film transistor according to the first embodiment;

FIG. 9 is a schematic view of an electron beam vapor deposition apparatus using the zinc tin complex oxide target according to the first embodiment;

FIG. 10 is a cross sectional view for explaining the integrated structure of an organic EL device and an oxide semiconductor thin film transistor according to a second embodiment;

FIG. 11 is a cross sectional view of a one time programmable thin film memory device (bottom gate top contact type) according to a third embodiment;

FIG. 12 is a schematic view of an active matrix circuit applied to a thin film memory device according to the third embodiment;

FIG. 13 is a bird's-eye view of an active matrix circuit applied to the thin film memory device according to the third embodiment;

FIG. 14A is a circuit diagram for explaining a bottom gate top contact type oxide semiconductor thin film transistor using a capacitor element on the side of a drain electrode according to the third embodiment;

FIG. 14B is a view showing an embodiment of a thin film memory according to the third embodiment, which is a cross sectional view for explaining a bottom gate top contact type oxide semiconductor thin film transistor using a capacitor element on the side of the drain electrode;

FIG. 15A is a view showing an embodiment of a thin film memory according to the third embodiment, which is a cross sectional view for explaining a bottom gate top contact type oxide semiconductor thin film transistor using a ferrodielectric material to a gate insulation film;

FIG. 15B is a view showing an embodiment of a thin film memory according to the third embodiment, which is a cross sectional view for explaining a bottom gate top contact type oxide semiconductor thin film transistor using a ferroelectric material to a gate insulation film; and

FIG. 16 is a cross sectional view for explaining a thin film semiconductor stacked memory conducting integration by stacking using a one time programmable thin film memory device according to the third embodiment as a basic structure.

### DESCRIPTION OF THE PREFERRED EMBODIMENTS

Preferred embodiments of the present invention are to be described.

For the oxide semiconductor target of the present application, ZTO (zinc tin complex oxide) with no addition of impurities is used. Both metallic zinc and tin as the starting materials have a Clarke number of 0.004%, which are present in a relatively large amount in the earth crust and can be said to be metal materials with no problems in view of the cost and amount of supply at present.

Since zinc oxide is a hexagonal system and tin oxide is a tetragonal system, ZTO as a mixture of them cannot maintain a single crystal structure and is basically in an amorphous state. Accordingly, it is apparent that they are material system with no problem in view of the cost, in view of the resource supply, and the effect of crystal grain boundary scattering.

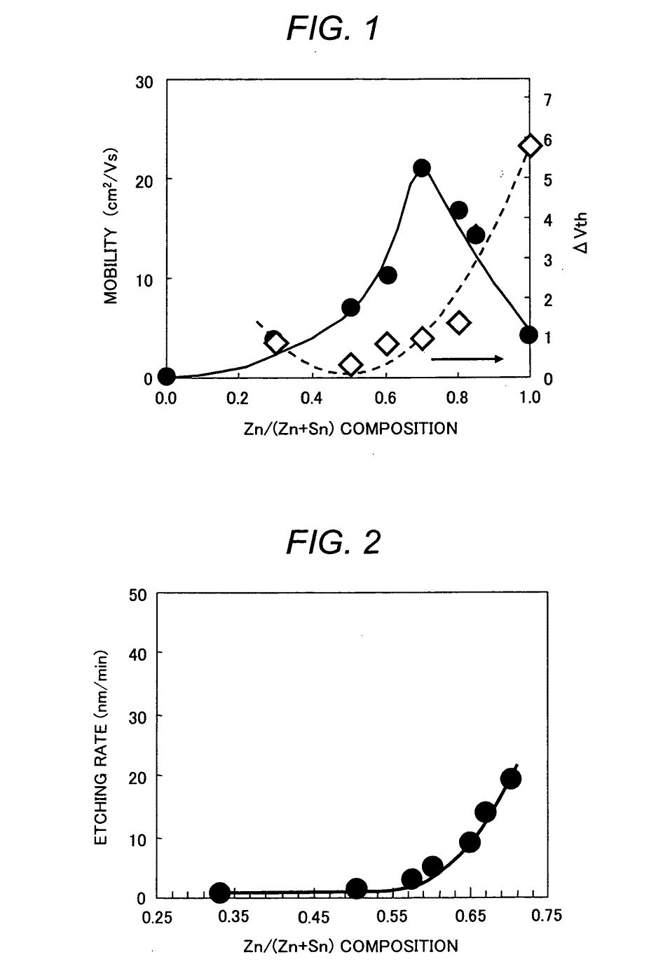

FIG. 1 shows the result of investigation for the relation between the Zn/(Zn+Sn) composition in a target and thin film transistor characteristics upon forming the thin transistor by using the ZTO target. At first, the mobility tends to be improved as the Zn/(Zn+Sn) composition is higher and it is considered that from 0.6 to 0.8 is a preferred compositional range where a mobility of about 5 cm²/Vs or higher is expected. In a compositional range higher than 0.8, lowering of the mobility is observed and this is estimated to be attributable to that the hexagonal system becomes predominant as the Zn composition is higher to increase grain boundaries.

On the other hand, for the threshold potential shift (ΔVth), it is most stable at a Zn/(Zn+Sn) composition of 0.5 is most stable, and it is considered that a compositional range from 0.3 to 0.8 is preferred in view of the range of the allowable potential shift within 2 V. Accordingly, judging from the device characteristics, it is considered that a preferred Zn/(Zn+Sn) composition is from 0.6 to 0.8. However, as the tin composition becomes higher, etching fabrication essential to the device manufacture tends to become difficult and the composition should be designed while considering the same.

FIG. 2 shows the result of investigation for the relation between an etching rate of a ZTO film using an oxalic acid type etching solution used for the fabrication of ITO used generally as a transparent electrode and a Zn/(Zn+Sn) composition. When an effective process throughput is taken into consideration, an etching rate of 5 nm/min or higher is required at the lowest and it can be seen that the composition capable of satisfying the requirement is 0.6 or higher. Accordingly, it can be seen that the Zn (Zn+Sn) composition that can satisfy also the etching fabrication condition while satisfying sufficient threshold potential stability and high mobility characteristics is within a range from 0.6 to 0.8. A target sintered in the compositional range is effective as a semiconductor target.

Further, such oxide materials have been so far discussed as the candidate for transparent conductive films and known example of transparent electrodes and sintered products are present, for example, as shown in Japanese Patent Application Laid-Open Publication No. 2006-196200, columns [0009] to [0032], Japanese Patent Application Laid-Open Publication No. 2006-194926, columns [0009] to [0030], Japanese Patent Application Laid-Open Publication No. 2007-277075, columns [0009] to [0058], and Japanese Patent Application Laid-Open Publication No. 2007-250369, columns [0005] to [0006]. The present invention cannot be considered identical with them. For example, while the known examples described above are mainly intended for forming transparent electrodes, since DC sputtering of high deposition rate is utilized, they are targets having high conductivity due to addition of impurities, etc. (resistivity of targets is effectively 1×10⁻³ Ωcm or lower), whereas the present invention provides a high resistance target for which discharge is impossible by DC sputtering.

Assuming that when deposition were conducted by using a target where excess carriers are present for forming a transparent electrode, since this forms a conductive film, an off state by a gate bias cannot be realized, and the operation as the semiconductor device is impossible, so that it is necessary to adopt a deposition method of utilizing an RF sputtering or a beam capable of discharging even for a target material at high resistance.

In the ZTO target of the present invention, the total concentration of impurities mainly contributing to the generation of carriers (boron, aluminum, gallium, indium, thallium, nitrogen, phosphorus, arsenic, antimony, and bismuth) is suppressed to 100 ppm or less. Further, a high resistance of 1 Ωcm or higher can be attained by introducing oxygen by an approximate stoichiometrical amount.

For suppressing the compositional deviation of oxygen that occurs during deposition, addition of an oxygen gas at a ratio of 10% or more in an Ar gas utilized generally as a sputtering gas is also effective for forming a semiconductor layer having good characteristics. A ZTO semiconductor layer having a resistivity of 1×10⁻¹ Ωcm or higher can be formed by deposition under the conditions as described above by utilizing the target material described above and this can function as a thin film transistor used mainly for display.

The method of forming the oxide semiconductor target is generally as described below. At first, an aqueous solvent is added to a powder mixture of zinc oxide and tin oxide at a high purity (99.999% or higher) as starting materials, and they are mixed for several hours or more to form a slurry. Polyvinyl alcohol or the like as a binder is added to the slurry and, after drying, pelleted powder is molded in a die frame, and baked in atmospheric air at about 600° C. for several hours in order to remove the binder in the solid product.

The solid product is further sintered in an atmospheric air or an oxygen atmosphere at a temperature of about 1300° C. for several hours or more to form a starting material for the target material. By the sintering in the atmospheric air, oxygen approximate to a stoichiometrical amount can be introduced into the target material. The obtained sintered product is formed into desired shape and size by grinding to complete a target material. In a case of using the material as a sputtering target, it can be bonded to a metal back plate on the side of the cathode electrode of the sputtering apparatus and can be used as the sputtering target.

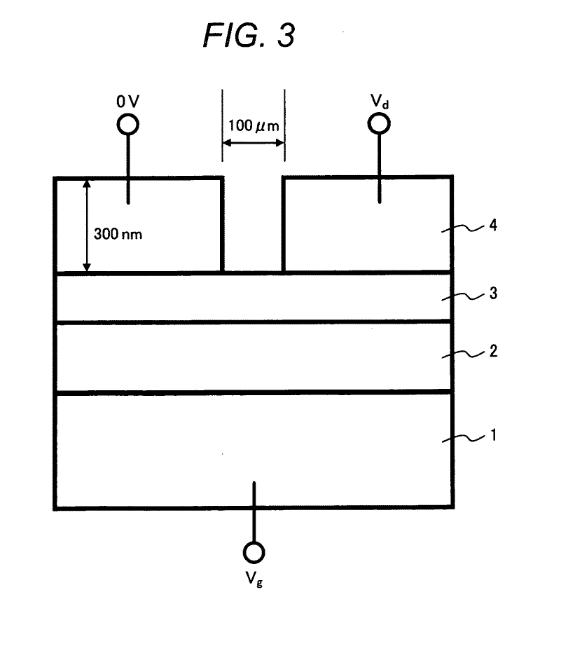

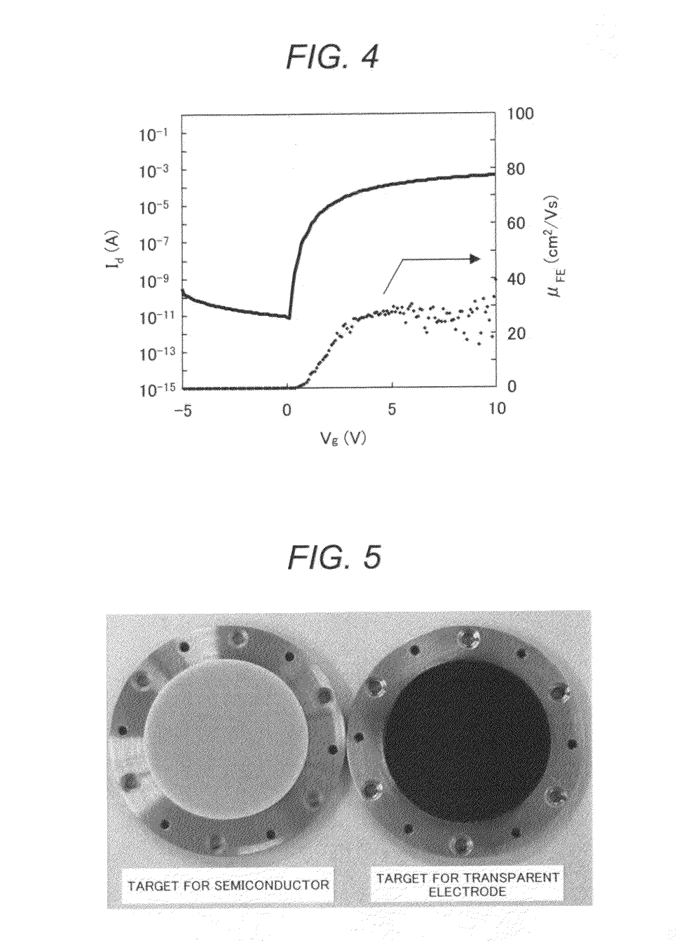

Then, FIG. 4 shows current-voltage characteristics in a case of manufacturing a thin film transistor structure as shown in FIG. 3 by RF sputtering deposition by utilizing a target having a Zn/(Zn+Sn) composition of 0.7 according to this embodiment.

This shows good semiconductor characteristics where also a threshold voltage is present near 0V and an ON/OFF ratio is 10⁶ or more. Since the threshold voltage is present near 0V, this also provides an auxiliary effect that the circuit design is facilitated. Further, since this is in the amorphous state and less undergoes the effect of the grain boundary scattering, a mobility of 20 cm²/Vs or more is also obtained even if the film thickness of the channel layer is as thin as about 25 nm. Also for the stability of the threshold potential which results a problem in a case of application to a display device such as a display, it is suppressed generally within ±1V, which can be said to be sufficient characteristics also in view of the reliability of the thin film transistor.

Further, by adopting the Zn/(Zn+Sn) composition of 0.7 according to this embodiment, since good condition can be ensured for the controllability and the throughput as the etching rate of 20 nm/min by an oxalic acid type wet etching solution at a room temperature, devices can also be manufactured easily by an existent photo-process used for the mass production process.

Further, the method of forming the thin film transistor using the oxide semiconductor target according to this embodiment is excellent in view of large area and uniformity and can realize a low temperature process when compared with deposition of a-Si, etc. by CVD (chemical vapor deposition method) at high temperature. Accordingly, a thin film transistor can be formed to a flexible large area substrate which is difficult to be processed at a high temperature, as well as the cost can be decreased also in the existent thin film transistor production process on a glass substrate.

Since it may suffice to apply modification, for example, introduction of an equipment such as RF sputtering only with respect to the channel layer deposition step for the thin film transistor or provision of an RF power source to a DC sputtering apparatus for forming a transparent electrode, and production is basically possible by an apparatus using a process substantially identical with that used for the existent thin film transistor manufacturing process for liquid crystal displays for other steps, the installation cost upon introduction of the equipment can also be suppressed.

The present invention is to be described specifically by way of embodiments.

### First Embodiment

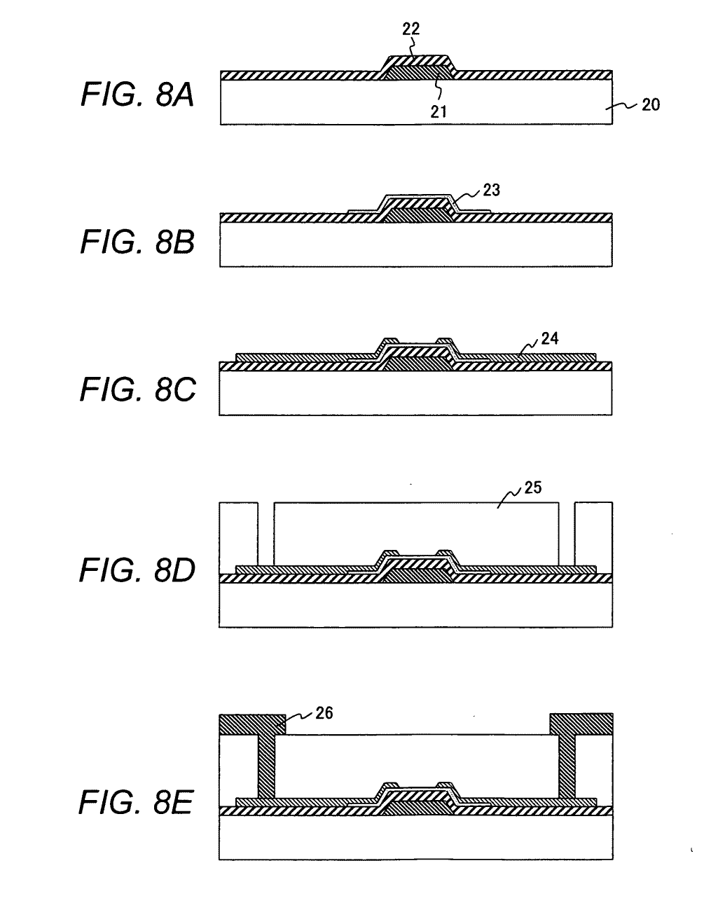

A first embodiment is to be described with reference to FIG. 5 to FIG. 7, and FIG. 8A to FIG. 8E. Those described in the column in preferred embodiments of the invention and not described in this embodiment are identical with those for the description of preferred embodiments of the invention.

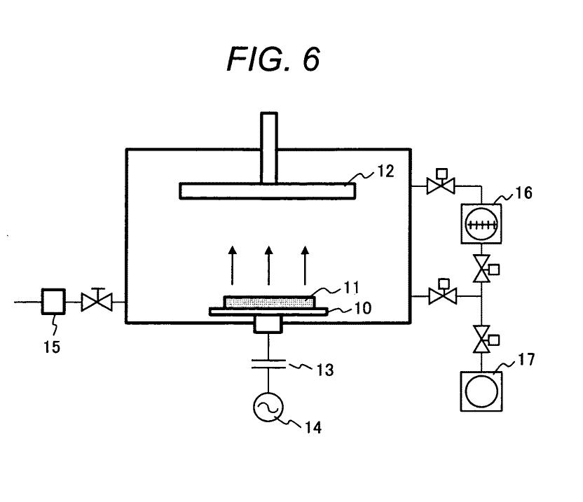

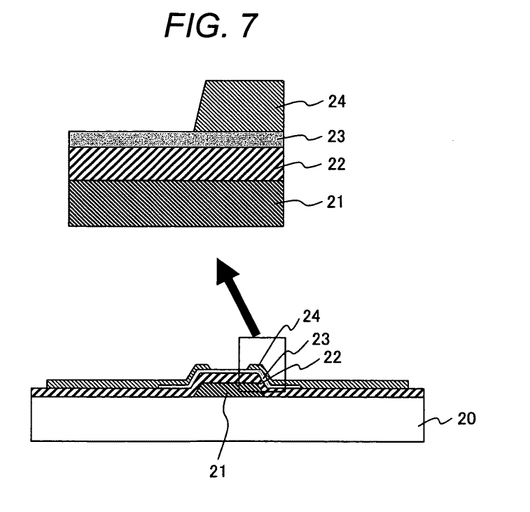

FIG. 5 is a photograph showing the difference of appearance between a sputtering target for a semiconductor and a sputtering target for a transparent electrode according to this embodiment. FIG. 6 is a schematic view of an RF sputtering apparatus applied with a sputtering target according to this embodiment, and FIG. 7 is a cross sectional view showing the structure of a thin film transistor utilizing the oxide semiconductor channel layer formed by applying the sputtering target according to this embodiment (upper view is a fragmentary cross sectional view). FIG. 8A to FIG. 8E are flow charts showing the method of manufacturing the thin film transistor.

A method of manufacturing the oxide semiconductor sputtering target according to this embodiment is to be described. At first, powders of zinc oxide and tin oxide highly purified (99.9999%) by the existent technique are weighed for each of the powders in such an amount of molar percent that the Zn/(Zn+Sn) composition is 0.7 and mixed into a slurry form by an aqueous solvent utilizing a mill, etc. The mixing time is set to 5 hours or more and, after sufficient mixing, a binder such as polyvinyl alcohol is added and, after drying, a pelleted powder is molded in a mold frame, a heating treatment is applied in an atmospheric air at about 600° C. for several hours with an aim of removing the binder to solidify the same. The solidified product is further applied with a baking treatment in an atmospheric air or in an oxygen atmosphere at about 1300° C. for 5 hours or more to form a sintered product having a relative density of 99% or higher.

Then, when the sintered product is shaped into a desired shape by grinding and bonded to a back plate of a cathode electrode of a sputtering apparatus, a completed sputtering target is obtained. As shown in FIG. 5, the color of the ZTO target completed by the method is glossy, exhibits whitish gray and can be distinguished at a glance from an oxide target having many oxygen defects which is used usually as a target for forming a transparent electrode and exhibits a deep black color. The target shows a resistivity of about 1 Ωcm or higher by measurement according to a 4-terminal method and greatly differs also in this respect relative from a target used for a transparent electrode that requires a resistivity of about 1×10⁻³ Ωcm or lower.

Since discharge by DC bias is difficult or the ZTO oxide semiconductor target manufactured as described above, sputtering deposition is applied by RF bias. For example, the resistivity of the ZTO thin film is 2.5 Ωcm when it was deposited by a ZTO stuttering target 11 according to this embodiment by using an RF sputtering apparatus as shown in FIG. 6 and using an argon gas with addition of an oxygen gas at about 15% as a sputtering gas, under the condition at a pressure of 0.5 Pa, an RF power density of 2.65 W/cm², and an inter-electrode distance of 80 mm. In the drawing, are shown a cathode electrode (backing plate) 10, a counter electrode (used also as a sample holder) 12, a matching box 13, an RF power source 14, a mass flow controller 15, a cryopump or molecule turbo pump 16, and a dry pump or rotary pump 17.

Further, a bottom gate top contact type thin film transistor structure as shown in FIG. 7 is manufactured by using a deposition technique of using the ZTO target according to this embodiment in a process flow as shown in FIG. 8A to FIG. 8E. At first, a support substrate 20 such as a glass substrate, a quartz substrate, a sapphire substrate, or a resin substrate is provided. Then, a metal thin film, for example, a stacked film of Al (250 nm) and Mo (50 nm) is formed by a vapor deposition method, a sputtering method or the like on the support substrate 20, patterned by a lift off process or etching process to form a gate electrode 21. Then, a gate insulator layer 22 formed of an oxide film or a nitride film, for example, a silicon oxide film or a silicon nitride film of about 100 nm thickness is deposited to the layer thereabove by a sputtering method, a CVD method or a vapor deposition method (FIG. 8A).

Then, a ZTO semiconductor channel layer 23 is formed by an RF sputtering method using the ZTO target, a mask is formed by a resist process, and etching is applied using an oxalic acid type etching solution or a hydrochloric acid type etching solution (FIG. 8B). In this case, an argon gas with addition of 15% oxygen was used as a sputtering gas. Oxygen can be added by 10% or more in such a range that the function of the argon gas is not deteriorated as the sputtering gas. The thickness of the ZTO semiconductor channel layer 23 is different depending on the device to be applied and it is preferably about 10 nm to 75 nm. As the etching solution, an etching solution containing an organic acid such as oxalic acid or acetic acid, or an etching solution containing an inorganic acid such as halogen type or nitrate type acid can be used. In a case of applying dry etching instead of wet etching, a halogen type gas may be used and, fluorine type gas is particularly suitable.

Then, an electrode layer as a source-drain electrode 24 is formed over the ZTO oxide semiconductor channel layer 23 by a vapor deposition method, sputtering or the like, and patterned by a lift off method or an etching process using a resist process is (FIG. 8C) and a bottom gate top contact type oxide semiconductor thin film transistor is completed by way of a step of forming a passivation layer 25 (FIG. 8D) and a step of forming an interconnection 26 (FIG. 8E). For the source-drain electrode 24, a transparent conductive layer formed of ITO, IZO, AZO (aluminum doped zinc oxide), or GZO (gallium doped zinc oxide) may also be used, or an existent metal material, for example, Al or a stacked Ti/Au layer may also be used.

Further, a ZTO thin film transistor of an identical structure was manufactured by way of trial using a deposition technique by an RF magnetron sputtering method instead of the RF sputtering method described above. The ZTO semiconductor channel layer has a 25 nm thickness, the deposition conditions are as described above and a substrate is rotated at a rotation speed of 5 rpm during deposition. Transparent ITO electrode having a gate electrode of an Al (250 nm)/Mo (50 nm) stacked layer and a source-drain electrode of 150 nm formed by sputtering is used. In the thin film transistor, the threshold potential shift is suppressed to 0.5 V or less for continuous use of 100 hours, and preferred values are also obtained for other basic characteristics such as 20 cm²/Vs or higher of mobility and 10⁶ or more of on-off ratio.

When the thin film transistor is applied as a transistor for driving an active matrix type liquid crystal display, it has been found that the transistor has sufficient characteristics and is durable to practical use. Also for the cost of manufacturing the panel, since a large area, high uniformity, low temperature process can be attained compared with a-Si thin film transistor using existent CVD, and the necessary cost is about only of the cost for the target, it is expected that the cost can be saved by about 10 to 20%.

In this embodiment, while description has been made referring to a case of the Zn/(Zn+Sn) composition of 0.7, the composition is not restrictive and substantially identical values can be obtained for the characteristics of the thin film transistor itself by utilizing the Zn/(Zn+Sn) composition of 0.6 to 0.8 as defined in the claims, although wet etching characteristics vary somewhat.

While the RF sputtering method and the RF magnetron sputtering method are used as the deposition method, a substantially identical result can be obtained also by shaping the target in a ring-like form and using a sputtering method using high frequency such as an ECR (electron cyclotron resonance) method. Further, while description has been made in this embodiment with reference to the example of the bottom gate top contact type thin film transistor, the invention is not restricted particularly to this structure and substantially identical characteristics can be obtained also in thin film transistors of any other structures, for example, a bottom gate bottom contact type, top gate top contact type, and a top gate bottom contact type.

Further, while description has been made for the embodiment to an example of application as a transistor for driving an active matrix type liquid crystal display, this can be utilized with no problem also as an organic EL current driving device by optimally designing the channel layer thickness, the gate insulator thickness, etc.

As described above, this embodiment can provide an appropriate Zn/(Zn+Sn) composition for a ZTO (zinc tin complex oxide) type oxide semiconductor material at having high mobility and threshold potential stability, and with less restriction in view of the cost and the resource and with less restriction in view of the process. Further, this embodiment can attain the material target and provide a method of manufacturing a good oxide semiconductor device which is prosperous as a thin film transistor for switching and current driving for next generation organic EL devices or liquid crystal displays.

### Second Embodiment

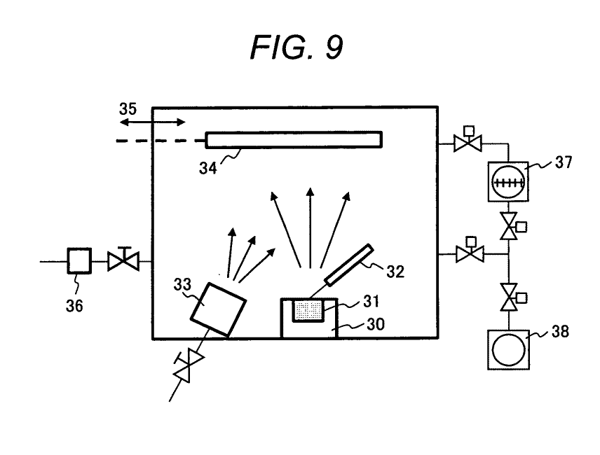

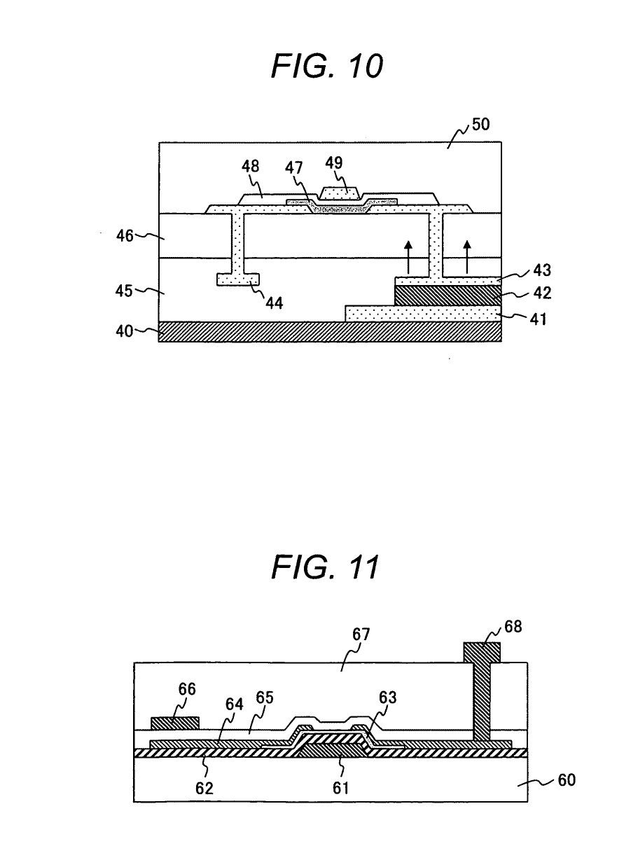

A second embodiment is to be described with reference to FIGS. 9 to 10. Matters described in the preferred embodiments of the invention, or those described in the first embodiment and not described in this embodiment are identical with those described in the preferred embodiment of the invention and in the first embodiment.

FIG. 9 is a schematic view of an electron beam vapor deposition apparatus using a low density oxide target according to this embodiment as an evaporation source. There are shown an evaporation source 30, an oxide target 31, an electron beam source 32, an ion source 33 (for ion assisting), a substrate holder 34, a substrate swinging device 35, a mass flow controller 36, a cryopump or molecule turbo pump 37, and a dry pump or rotary pump 38.

FIG. 10 is a cross sectional view showing a portion of a basic structure of an organic EL display using a thin film transistor manufactured by using an oxide semiconductor target according to this embodiment for a driving transistor. There are shown a back panel 40, an organic EL device electrode 41, an organic EL device 42, an organic EL device electrode (emission side) 43, a source-drain electrode 44, an organic insulator layer 45, an interlayer insulator layer 46, a ZTO semiconductor channel layer 47, a gate insulator 48, a gate electrode 49, and a passivation film 50.

In a case of a target of applying a beam, a target having so high density is not necessary and a shape of so large size is not required with a view point of the beam diameter. The basic method of manufacturing the target is substantially identical with that for the first embodiment. In a case of not requiring a high density, a step of mixing a binder and a high temperature baking step at 1,300° C. may be saved with no practical problems. Further, a method of simply mixing powders of zinc oxide and tin oxide at high purity so as to provide a ZN/(Zn+Sn) composition of 0.6 to 0.8 precisely and molding the same into a desired shape by compression high pressure is sufficient for practical use.

A target of 20 mmφ and 10 mm thickness manufactured by the method described above is applied to the electron beam vapor deposition apparatus as shown in FIG. 9. In the same manner as the sputtering target of the first embodiment, while a target used for the transparent electrode exhibits a black color with many oxygen defects, since the ZTO target used for the semiconductor application exhibits a whity color with less oxygen defects, it can be confirmed at a glance. The target for semiconductor use has a feature that the resistivity of the target itself shows a resistivity as high as 10 Ωcm, whereas the target for the conductive film use has a resistivity of 1×10⁻² Ωcm or lower.

When the ZTO semiconductor target 31 according to this embodiment is set to the evaporation source 30, a deposition rate of about 5 nm/min is obtained at an acceleration voltage of 6 kV and a beam current of 70 mA. Deposition at higher density is also possible by introducing an oxygen ion assist from the ion source 33 during deposition. Further, deposition substantially at room temperature is also possible by applying cooling on the side of the substrate.

A thin film transistor is formed by a method basically identical with that in the first embodiment by electron beam vapor deposition while utilizing the ZTO target (Zn/(Zn+Sn) composition of 0.65) as the evaporation source. However, since this is formed as an integrated structure with a bottom emission type organic EL device in this embodiment, a top gate bottom contact type thin film transistor structure is adopted. The ZTO channel layer 47 has a 50 nm thickness. The deposition conditions are as described above and the substrate swinging device 35 is used with an aim of improving the deposition distribution during deposition. An AZO transparent electrode having a gate electrode 49 of an Al (250 nm)/Mo (50 nm) stacked film and a source-drain electrode 44 of 150 nm thickness formed by sputtering is used.

In the thin film transistor, the threshold potential shift is suppressed to 0.7 V or lower in continuous use for 100 hours and good values are obtained for other basic characteristics such as a mobility of 30 cm²/Vs or higher and an on/off ratio of 10⁷ or more. When the thin film transistor is applied as a transistor having the basic structure as shown in FIG. 10 in an array structure for driving an active matrix type organic EL display, it can be confirmed that the transistor has sufficient characteristics.

While deposition by the electron beam vapor deposition method is shown in this embodiment, substantially the same effect can be expected also by using ion plating or a pulse laser vapor deposition method that utilizes a beam as a vapor deposition source. Further, it is needless to say that the transistor can be utilized with no problem also as a switching device for active matrix type liquid crystal displays.

As described above, this embodiment has the same effect as the first embodiment. Further, since the oxide semiconductor film is deposited by using the electron beam, and the target density can be lowered, and the manufacturing step of the oxide semiconductor target can be simplified, so that the cost for the target can be decreased.

### Third Embodiment

A third embodiment is to be described with reference to FIGS. 11 to 14. Matters described in the preferred embodiments of the invention, or those described in the first embodiment and not described in this embodiment are identical with those described in the preferred embodiments of the invention and in the first embodiment.

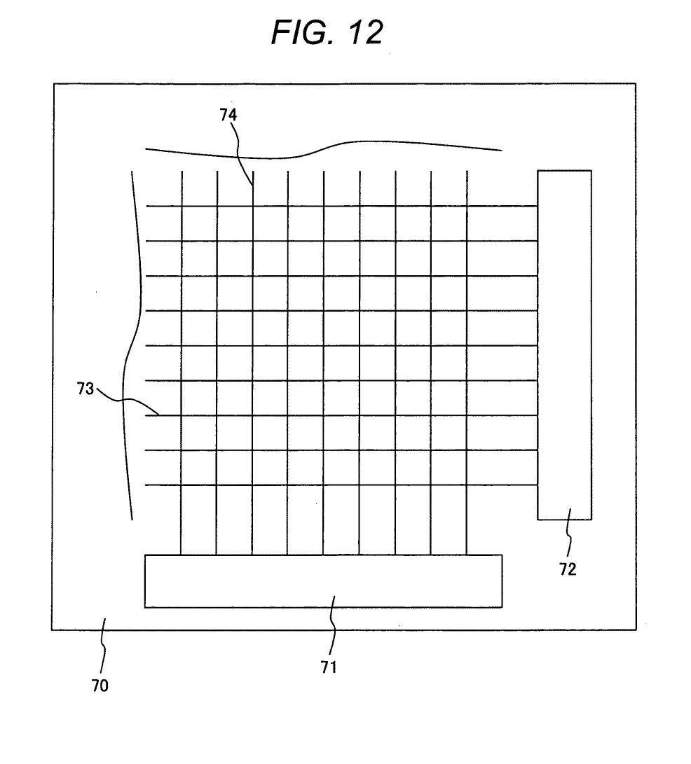

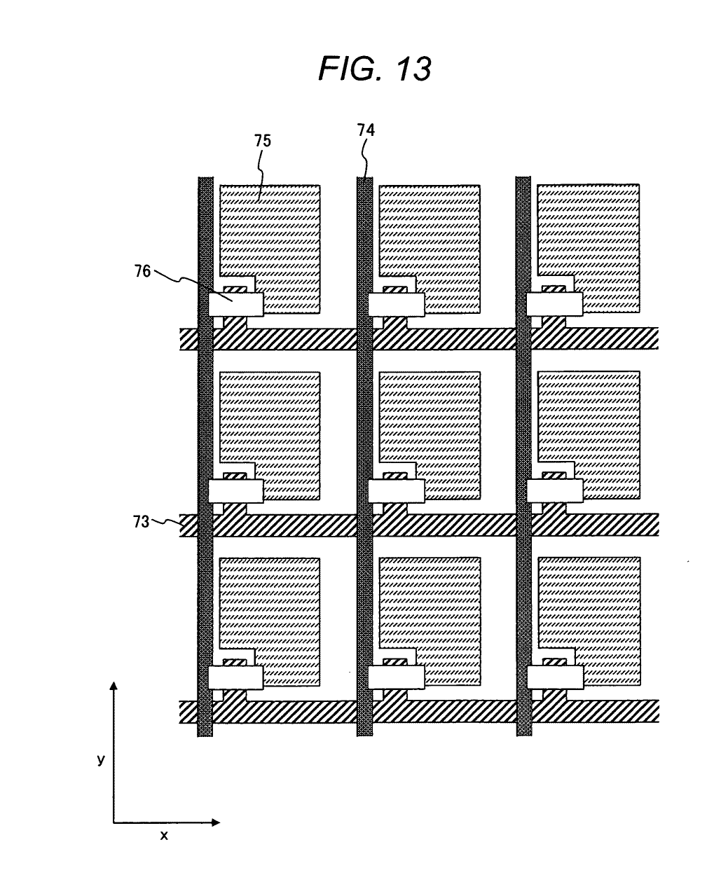

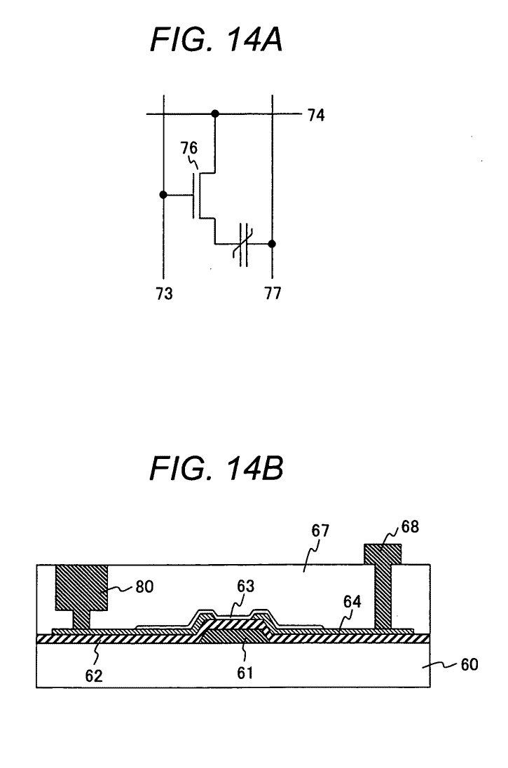

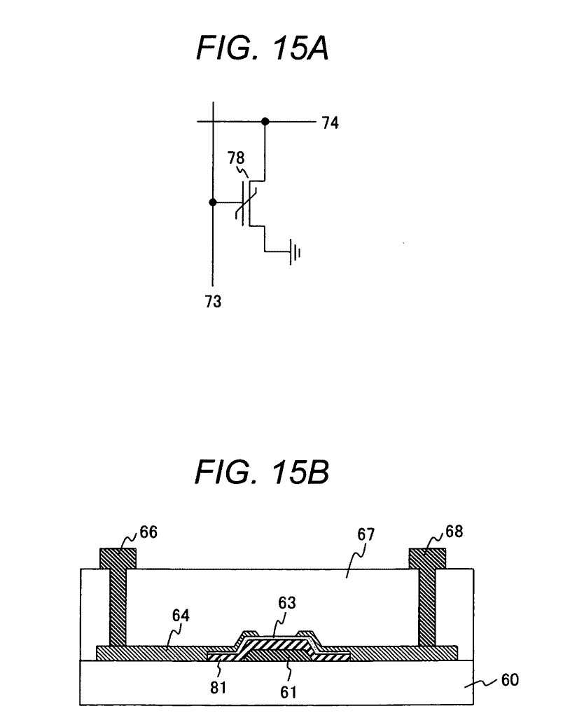

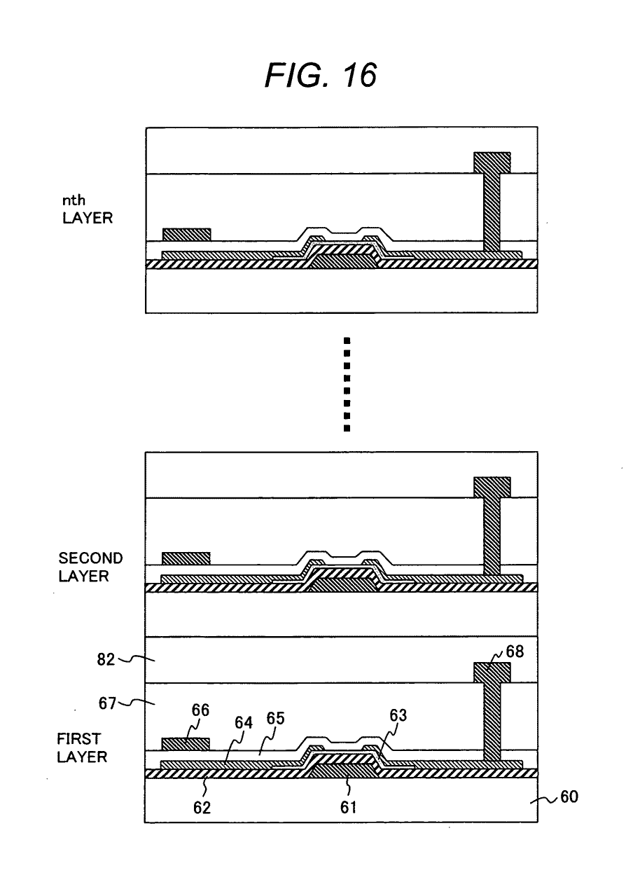

FIG. 11 is a cross sectional view of a one time programmable memory cell having a bottom gate top contact type thin film transistor formed by using the ZTO target according to the first embodiment or the second embodiment as a basic structure, FIG. 12 is a configurational view of an oxide semiconductor memory according to this embodiment, FIG. 13 is a bird's-eye view of an carry for oxide semiconductor thin film transistors according to this embodiment, FIG. 14A is a circuit diagram of a programmable using oxide semiconductor thin film transistor memory device and incorporated with a capacitor element on the side of a drain electrode, FIG. 14B is a cross sectional view for the device thereof, FIG. 15A is a circuit diagram of a programmable ferrodielectric memory device that conducts memory operation due to the change of the gate capacitance by using an oxide semiconductor thin film transistor and utilizing a ferrodielectric material for the gate insulator, FIG. 15B is a cross sectional view for the device thereof and, FIG. 16 is a cross sectional view in which an oxide semiconductor memory according to this embodiment is multilayered and integrated.

By using the ZTO target according to the first embodiment or the second embodiment and using the same deposition technique as in the first embodiment and the second embodiment, a thin film transistor array having the thin film transistor structure as shown in FIG. 11 as the basic structure is formed. The configuration of the thin film transistor array is as shown in FIGS. 12 and 13. There are shown a support substrate 70, a data line driving circuit 71, a gate line driving circuit 72, gate lines 73, data lines 74, a drain electrode 75 (corresponding to the pixel electrode of display), and a ZTO thin film transistor 76.

For the memory application, the thickness of the gate insulator 62 is preferably about from 10 nm to 50 nm (refer to FIG. 11). Then, the ZTO oxide semiconductor channel layer 63 is formed by an RF sputtering method or an electron beam vapor deposition method. ZTO deposition conditions are identical with those in the first embodiment except for the addition ratio of oxygen. Considering the characteristics as the memory, a channel layer thickness that can be completely depleted is from 5 to 15 nm, and it is necessary to select a combination of film thicknesses considering them.

Then, after forming the source-drain electrode 64 layer by a vapor deposition method or a sputtering method, a pattern of a source-drain electrode 64 is formed by a resist process and etching or a lift off process. Further, a resistor layer 65 formed of silicon oxide film/silicon nitride film is formed thereover, and an interconnection layer 66 is placed at a position adjacent therewith.

By skillfully setting the thickness for the resistor layer 65 and the interconnection layer 66 by a well known technique, since the resistor layer 65 is destroyed to establish provide conduction by applying a somewhat high voltage in the initial stage, a one time programmable memory can be attained by utilizing the same. In the drawing, are shown a support substrate 60, a gate electrode 61, an interlayer insulator layer 67, and an interconnection layer 68 (on the side of the source).

Further, by forming a capacitance layer 80 having a sufficient capacitance to the portion as shown in FIG. 14B, or forming the gate insulator 81 with a ferrodielectric material such as PZT (Pb(Zr,Ti)O₃), SBT (SrBi₂Ta₂O₉), BLT ((Bi,La)₄Ti₃O₁₂), etc. as shown in FIG. 15B. In this case, it can be utilized as a programmable memory. When the capacitance layer 80 is provided on the side of the drain electrode as shown in FIG. 14B, the difference of the current value due to hysteresis is utilized as the memory, whereas the difference of the threshold potential is utilized as the memory in a case of forming the gate insulator 81 with the ferrodielectric material, etc. as shown in FIG. 15B.

Further, a memory array is completed by forming an interlayer insulator 67 including a polyimide or SOG (Spin On Glass) layer, forming a through hole and forming an interconnection layer 68. In the drawing, are shown a capacitance value reference line 77, and a ZTO thin film transistor 78 using a ferrodielectric material gate insulator. Since the technique of the present invention mainly includes a deposition technique, it is possible to increase the memory capacitance or integration of the circuit per unit area by stacking the memory arrays (drawing shows an example of once programmable memory) toward the upper layer region as shown in FIG. 16. Reference 82 shows an interlayer insulator (planarization layer).

As a result of actually investigating the current-voltage characteristics of a unit cell of the ZTO thin film transistor manufactured by the method of this embodiment, it shows good transistor characteristics with the subthreshold swing of 72 mV/dec and the mobility of 15 cm²/Vs. Further, since the threshold potential of this transistor is present at about 0 V, memory operation at a super low voltage (1.5 V or lower), with a super low consumption power is possible also in conjunction with a good subthreshold swing characteristic. While description has been made herein with reference to the bottom gate top contact type thin film transistor, substantially identical effect can be obtained also in other thin film transistor structures such as in any of a top gate bottom contact type, a top gate top contact type, or a bottom gate bottom contact type.

Further, since ZTO is a transparent oxide material, an almost transparent circuit can be formed when the material is used as the thin film transistor while using a silicon oxide film for the gate insulator and using a transparent conductive layer formed, for example, of ITO, AZO, or GZO for the electrode material. For example, in a case of forming an electrode portion and an antenna portion with an a transparent conductive ITO layer, and forming RFID having a power source circuit or resonance circuit (utilizing ZTO semiconductor Schottky diode), and a digital circuit applied with a one time programmable memory shown in FIG. 11 with the ZTO thin film transistor of the present application, transmission/reception at 13.56 MHz could be confirmed.

Particularly, as the feature of the RFID tag, since it is formed of a material having an extremely high transmittance of 90% or higher, and it is not in the configuration where Si chip or the structure of antenna, etc. made of metal are visible as in the existent RFID tag, it can be attached subsequently without deteriorating the design described on the film or the card. While description has been made in this embodiment for the application of the ZTO thin film transistor to the memory, it is of course possible for application to other circuits, and a device where each of the circuits is laminated on every layer can also be attained.

According to this embodiment, the same effect as in the first and the second embodiments can be obtained. Further, since the low temperature process is used, a stacked device can be manufactured easily.

Further, while the oxalic acid type etching solution is used as the etching solution described in each of the embodiments, an etching solutions containing an organic acid such as acetic acid, or an inorganic acid of halogen type or nitric acid type can also be used.

While the inventions made by the present inventors have been described specifically with reference to the first to third embodiments, it will be apparent that the invention is not restricted to the embodiments described above and can be modified variously within a range not departing the gist thereof.

What is claimed is:

1. An oxide semiconductor target with an aim of forming a thin film oxide semiconductor, which is a sintered oxide comprising zinc oxide and tin oxide (IV or VI) is a main ingredient wherein a composition of zinc (Zn) and tin (Sn) (Zn/(Zn+Sn)) is from 0.6 to 0.8, and the electric resistivity of the sintered body is 1 Ωcm or higher.

2. An oxide semiconductor target according to claim 1, wherein the composition (Zn/(Zn+Sn)) is from 0.65 to 0.7.

3. An oxide semiconductor target according to claim 1, wherein the total concentration of boron, aluminum, gallium, indium, thallium, nitrogen, phosphorus, arsenic, antimony, and bismuth in the sintered oxide is 100 ppm or less.

4. An oxide semiconductor target according to claim 1, wherein the thin film oxide semiconductor is used as a channel layer of a thin film transistor or a hetero structure field effect transistor.

5. A method of manufacturing an oxide semiconductor device using the oxide semiconductor target according to claim 1, and depositing an oxide semiconductor film as a channel layer by a sputtering method using high frequency waves.

6. A method of manufacturing the oxide semiconductor device according to claim 5, wherein
the oxide semiconductor film has a resistivity of 1×10⁻¹ Ωcm or higher.

7. A method of manufacturing an oxide semiconductor device according to claim 5, wherein
a sputtering gas used for the sputtering method using the high frequency waves contains 10% or more of an oxygen gas.

8. A method of manufacturing an oxide semiconductor device according to claim 5, wherein
the sputtering method using the high frequency waves is an RF sputtering, RF magnetron sputtering, or electron cyclotron resonance sputtering.

9. A method of manufacturing an oxide semiconductor device according to claim 7, wherein
the sputtering gas comprises argon as a main ingredient.

10. A method of manufacturing an oxide semiconductor device according to claim 5, wherein
deposition is conducted by a deposition method applying a beam instead of the sputtering method by using the high frequency waves.

11. A method of manufacturing an oxide semiconductor device according to claim 10, wherein
the deposition method by applying the beam is electron vapor deposition, ion plating, or pulse laser vapor deposition in an oxygen containing atmosphere.

12. A method of manufacturing an oxide semiconductor device according to claim 5, comprising:
etching the oxide semiconductor film with an etching solution including an organic acid as a main ingredient or an etching solution including an inorganic acid as a main ingredient.

13. A method of manufacturing the oxide semiconductor device according to claim 12, wherein
the organic acid is oxalic acid or acetic acid, and the inorganic acid is a halogen type or a nitric acid type.

14. A method of manufacturing an oxide semiconductor device according to claim 5, comprising:
fabricating the oxide semiconductor film by dry etching.

15. A method of manufacturing an oxide semiconductor device according to claim 14, wherein
the etching gas used for the dry etching is a halogen type gas.

16. A method of manufacturing an oxide semiconductor device according to claim 15, wherein
the etching gas used for the dry etching contains fluorine.

17. An oxide semiconductor target for depositing a thin film semiconductor film, in which
a composition of zinc (Zn) and tin (Sn) (Zn/(Zn+Sn)) is from 0.6 to 0.8,
an electric resistivity is 1 Ωcm or higher, and
the total concentration of boron, aluminum, gallium, indium, thallium, nitrogen, phosphorus, arsenic, antimony, and bismuth in the sintered oxide is 100 ppm or less, and
the target is a sintered oxide comprising zinc oxide and tin oxide as a main ingredient.
